(19) United States
(12) Patent Application Publication
(10) Pub. No.: US 2005/0287714 A1
(43) Pub. Date: Dec. 29, 2005

(54) Enhancing epoxy strength using kaolin filler

(76) Inventors: Michael Walk, Mesa, AZ (US); Paul A. Koning, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/881,377

(22) Filed: Jun. 29, 2004

(51) Int. Cl. H01L 21/44

(52) U.S. Cl. 438/127; 438/106; 438/126

(57) ABSTRACT

An embodiment of the present invention is a technique to provide a substrate with enhanced strength. A kaolin filler is added to an epoxy resin. The kaolin filler is mixed with the epoxy resin to form a mixture. A substrate is formed from the mixture. The substrate is processed in a package containing a semiconductor device.

### BACKGROUND

1. Field of the Invention

Embodiments of the invention relate to the field of semiconductor, and more specifically, to semiconductor materials.

2. Description of Related Art

Electronic packaging is one of the most materials-intensive applications. A variety of materials are used in packaging technologies; these include semiconductors, ceramics, glasses, polymers, and metals. Among the most important characteristics of packaging materials is the low coefficient of thermal expansion (CTE). High performance packaging substrates typically require low CTE to reduce stress on low and ultra low k interlayer dielectrics (ILDs) used in semiconductor devices such as microprocessors.

Existing techniques to reduce the CTE for substrates have a number of disadvantages. One technique is to replace organic materials with ceramic materials. However, ceramic substrates have high cost and exhibit poor tolerance on dimensional features. Another technique is to add rubber fillers to dielectric epoxies. There is a limit to the amount of rubber-based fillers that may be added as they can lower the modulus of the epoxy and increase the viscosity and affect subsequent downstream processing.

### BRIEF DESCRIPTION OF THE DRAWINGS

Embodiments of the invention may best be understood by referring to the following description and accompanying drawings that are used to illustrate embodiments of the invention. In the drawings:

FIG. 1 is a diagram illustrating a semiconductor device package in which one embodiment of the invention can be practiced.

FIG. 2 is a flowchart illustrating a process to provide a substrate with enhanced strength according to one embodiment of the invention.

FIG. 3 is a flowchart illustrating a process to process the material which is used as a substrate core in a package containing a semiconductor die according to one embodiment of the invention.

FIG. 4 is a flowchart illustrating a process to process the material which is used as a build-up layer in a package containing a semiconductor die according to one embodiment of the invention.

### DESCRIPTION

An embodiment of the present invention is a technique to provide a substrate with enhanced strength. A kaolin filler, or modifier, is added to an epoxy resin. The kaolin filler is mixed with the epoxy resin to form a mixture. A substrate is formed from the mixture. The substrate is then processed into a semiconductor device package.

Another embodiment of the invention is a substrate assembly attached to a semiconductor device. A substrate core has a throughhole. A build-up layer deposited on the surface of the substrate core has traces and vias connected to the throughhole and to the interconnecting layer of the semiconductor device or a plurality of bumps. At least one of the substrate core and the build-up layer is formed by a mixture of a kaolin filler and an epoxy resin.

In the following description, numerous specific details are set forth. However, it is understood that embodiments of the invention may be practiced without these specific details. In other instances, well-known circuits, structures, and techniques have not been shown to avoid obscuring the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a procedure, a method of manufacturing or fabrication, etc.

One embodiment of the invention is to provide a substrate material with enhanced strength or toughness. The substrate material may also have a low coefficient of thermal expansion (CTE). It can be used as a reliable build-up layer or a substrate core material in a semiconductor device package. It can also be used as a low cost substrate material for board, interposer and other packaging applications.

One embodiment of the invention offers the following advantages: (1) providing a tougher substrate for low k and/or ultra low k semiconductor packages, (2) meeting or exceeding electrical requirements for low and/or high performance semiconductor package substrates, (3) providing scalable and multi application substrate package technology for many generations, (4) providing a substrate package which can be manufactured using more than 90% of existing supplier high volume manufacturing (HVM) infrastructure, and (5) providing a low cost alternative for existing resins.

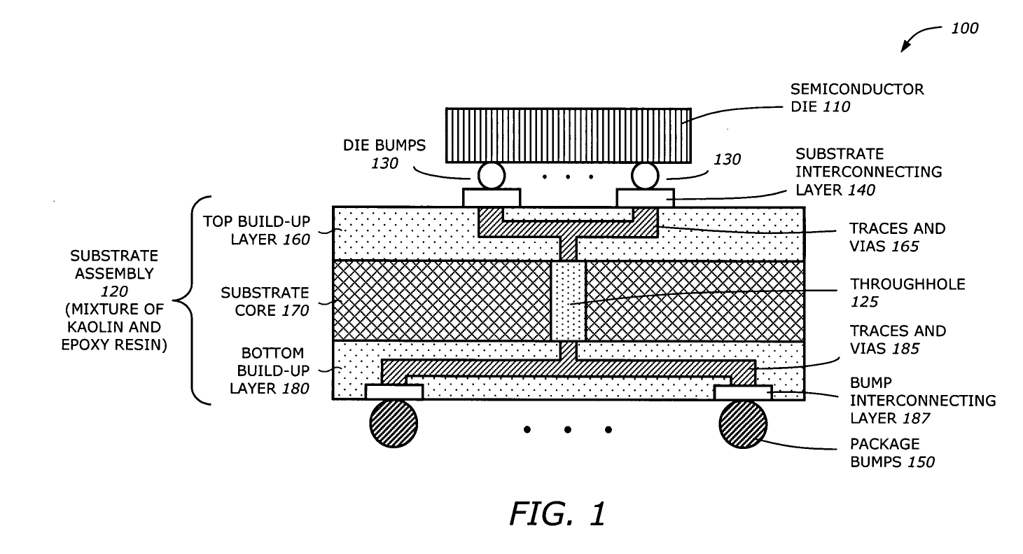

FIG. 1 is a diagram illustrating a semiconductor device package 100 in which one embodiment of the invention can be practiced. The device package 100 includes a semiconductor die 110 and a substrate assembly 120.

The semiconductor die 110 is any semiconductor device such as an integrated circuit (IC), a processor, a chip, a chipset, a logic circuit, or a memory device. It has a plurality of die bumps 130. The bumps 130 are electrically and mechanically connected to a substrate interconnecting layer 140 which in turn is in electrical and mechanical contact with the substrate assembly 120.

The substrate assembly 120 provides the package for the semiconductor die 110. It has a plurality of package bumps 150 at the bottom used to connect to a printed circuit board (PCB) or any other device. It includes a top build-up layer 160, a substrate core 170, and a bottom build-up layer 180. The substrate assembly 120 may include more or fewer components as above. For example, it may include the top build-up layer 160 and the substrate core 170, or the bottom build-up layer 180 and the substrate core 170.

The top build-up layer 160 provides interface between the substrate core 170 and the die 110. It is deposited on the top surface of the substrate core 170 between the substrate core 170 and the die 110. It has traces and vias 165 that are connected to the substrate interconnecting layer 140. The substrate core 170 is the main package substrate component. It typically has a low CTE. It has a throughhole 175 to serve as a conducting conduit between the die 110 and the package bumps 150. The bottom build-up layer 180 provides interface between the substrate core 170 and the package bumps 150. It is deposited on the bottom surface of the substrate core 170 between the substrate core 170 and the plurality of bumps 150. It has traces and vias 185 that are connected to a bump interconnecting layer 187. The bump interconnecting layer 187 is electrically connected to the package bumps 150. The traces and vias of the top and bottom build-up layers 160 and 180 are connected to the throughhole 175 in the substrate core 170. They are typically formed by using imprinting lithography and are typically plated with a suitable conducting material such as copper.

The substrate assembly 120 has an enhanced strength or toughness to provide a reliable substrate package for low and ultra low k semiconductors in a cost effective manner. At least one of the substrate core and build-up layers is formed by a mixture of a kaolin filler and an epoxy resin. Since kaolin is a low cost filler or modifier, the substrate assembly 120 can be formed at low cost. Any one of the top build-up layer 160, the substrate core 170, and the bottom build-up layer 180 may be made by a substrate material that contains a mixture of kaolin filler and epoxy resin.

The mixture of the kaolin filler and the epoxy resin comprises a weight percentage of the kaolin filler. The weight percentage may be selected to provide desired strength. In one embodiment, the weight percentage is between 10% to 70%. The strength or toughness of the mixture substrate of the top build-up layer 160, the substrate core 170, and the bottom build-up layer 180 may be the same or different. The weight percentages of the kaolin filler in either the top build-up layer 160, the substrate core 170, or the bottom build-up layer 180 may be the same or different. The mixture may also include a coupling agent to promote the mixing of kaolin filler and the epoxy resin, to facilitate the dispersion of the kaolin filler during the mixing operation, and to reduce agglomeration.

When used as a substrate dielectric material, the exact substrate dielectric formulation may have various compositions, depending on its performance requirements (e.g., physical properties such as viscosity, strength, and hardness, and electrical properties such as the dielectric constant k). A generic example of a curable substrate dielectric formulation may include epoxy resins, phenolic hardeners, catalyst (including photoactive and thermally active amine, anhydride or imidazole type catalyst), solvents to facilitate blending and conversion to a thin film, kaolin fillers, silica fillers, etc. Optionally, coupling agents to ease mixing and distribution of the kaolin in the epoxy mixture, thixotropic agent for viscosity control (for example, fumed silica), foaming inhibitors, pigments or dye, and flame retardants may also be included.

Of course, in other embodiments of a dielectric formulation more, less, or different components than those shown above can be used. For example other polymer resins such as polyesters, polyetheresters, polyamides, polyesteramides, polyurethanes, polyimides, polyetherimides, polyureas, polyamideimides, polyphenyleneoxides, phenoxy resins, epoxy resins, polyolefins, polyacrylates, polystyrenes, ethylene vinyl alcohols copolymer (EVOH), and the like or their combinations and blends can be used. Other polymers not listed here and their combinations or blends can also be used.

The silica and kaolin fillers may be pre-treated for the purposes of dispersion of the filler in the dielectric matrix and/or improving the strength of the polymer/clay interface. Any treatment that achieves the above goals may be used. Examples of useful treatments include intercalation with water-soluble or water-insoluble polymers, organic reagents or monomers, silane, titinate, zirconate or aluminate coupling agents, and/or their combinations. Alternately, these filler treatments/coupling agents can be added during the main mixing steps.

Typically these components are charged into a double planetary mixer with the fillers added last to assure proper wetting. This blend is allowed to mix until a uniform and flowable material is achieved. This mixture is optionally transferred to a three-roll mill for more intensive distribution of the kaolin filler. The addition of the catalyst is often delayed until this point to avoid premature reaction in the double planetary mixer. After multiple passes through the three-rolled mill the material is cast as a thin film on a release liner and the solvent removed. The material can be laminated at this point or a separate release line can be added and the rolled on a spool for storage.

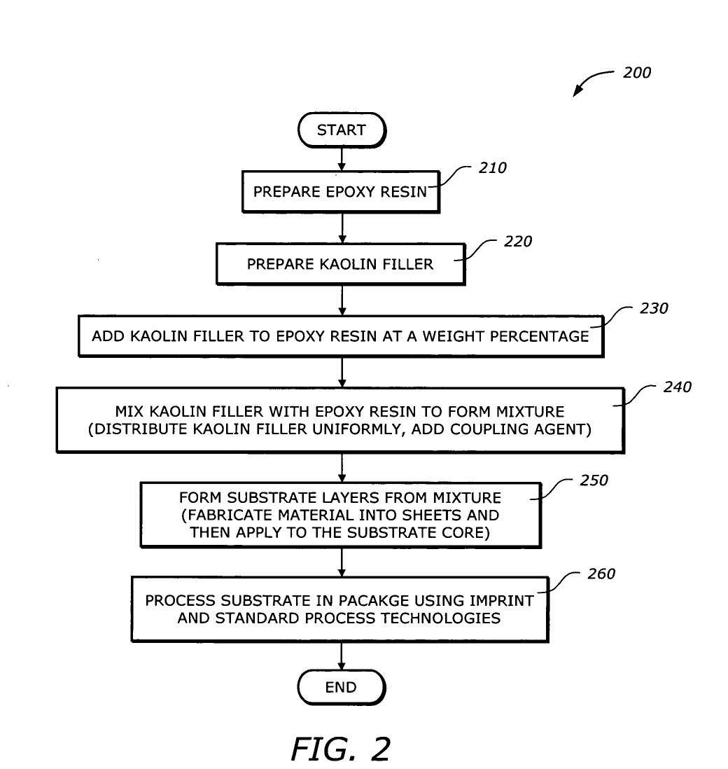

FIG. 2 is a flowchart illustrating a process 200 to provide the substrate with enhanced strength according to one embodiment of the invention.

The process 200 begins by adding kaolin filler to the epoxy resin. This can be performed by preparing the epoxy resin (Block 210), then preparing the kaolin filler (Block 220), and then adding the kaolin filler to the epoxy resin at a desired weight percentage. The purity and/or particle size of the kaolin filler may be selected to provide variations for the substrate material.

Next, the process 200 mixes the kaolin filler with the epoxy to form a mixture (Block 240). This can be performed by using a special mixer that can distribute the kaolin filler uniformly in the epoxy resin. To promote the mixing and to reduce agglomeration, a coupling agent may be added to the mixture. Then, the process 200 forms the substrate layers from the mixture (Block 250). This is done by fabricating the mixed material into substrate sheets that can be used as the substrate core or the build-up layer in the package. Next the sheet material is applied to the core of the substrate.

Next, the process 200 forms substrate features using imprint technology and existing substrate processes such as plating, curing and etching (Block 260). The substrate sheet material may be used for the substrate core or any one of the build-up layers, or both the substrate core and the buildup layer. The process 200 is then terminated.

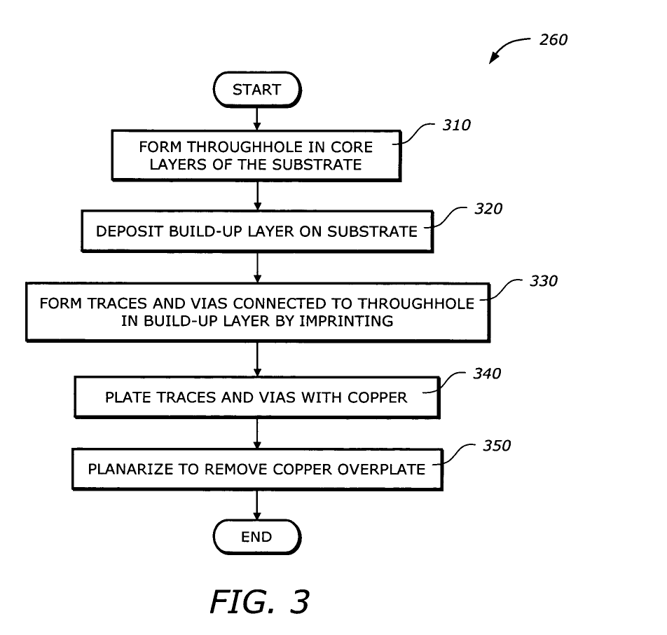

FIG. 3 is a flowchart illustrating the process 260 to process the material which is used as a substrate core in a package containing a semiconductor die according to one embodiment of the invention.

At the start of process 260, a throughhole is formed in the core layer of the substrate (Block 310). The core layer resin may contain a mixture of kaolin filler and epoxy resin. Next, kaolin and resin based sheets are applied to the core to form a build-up layer (Block 320). The build-up layer may or may not have a mixture of kaolin and epoxy resin. The build-up layer may be the top or bottom layer of the substrate assembly. Then, traces and vias are formed in the build-up layer using imprint (Block 330). The traces and vias are electrically connected to the throughhole in the substrate.

Next, the traces and vias are plated with a conducting material such as copper (Block 340). Then, the excess copper overplate is removed using planarizing techniques (Block 350). The process 260 can then be repeated for subsequent layers or stopped.

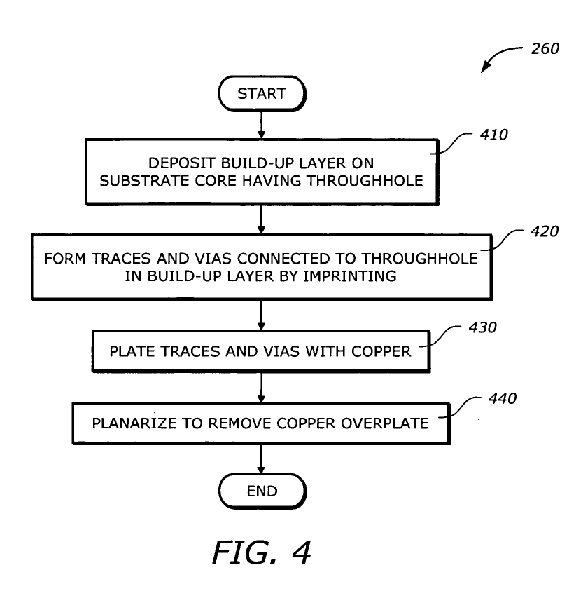

FIG. 4 is a flowchart illustrating in more detail the process 260 to manufacture the material which is used as a build-up layer in a package according to one embodiment of the invention.

The process 260 begins by depositing the build-up layer on a substrate core having a throughole (Block 410). The build-up layer contains a mixture of kaolin filler and epoxy resin. The substrate core may or may not have a mixture of kaolin and epoxy resin. The build-up layer may be the top or bottom layer. Then, the process 260 forms traces and vias in the build-up layer (Block 420). The traces and vias are electrically connected to the throughhole in the substrate core. The traces and vias may be formed using an imprinting technology to provide fine features on the substrate.

Next, the process 260 plates the traces and vias with a conducting material such as copper (Block 430). Then, the excess copper overplate is removed using planarizing techniques (Block 440). The process 260 can then be repeated for subsequent build-up layers or stopped.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

1. A method comprising:
adding a kaolin filler to an epoxy resin;
mixing the kaolin filler with the epoxy resin to form a mixture;
forming a substrate from the mixture; and
processing the substrate in a package containing a semiconductor die.

2. The method of claim 1 wherein adding comprises:
preparing the epoxy resin;
preparing the kaolin filler; and
adding the kaolin filler to the epoxy resin at a weight percentage.

3. The method of claim 2 wherein the weight percentage is between 10% to 70%.

4. The method of claim 2 wherein mixing comprises:
distributing the kaolin filler uniformly within the epoxy resin.

5. The method of claim 2 wherein mixing comprises:
adding a coupling agent to the mixture.

6. The method of claim 1 wherein forming the substrate comprises:
fabricating the mixture into a sheet, the sheet being used as a substrate core or a build-up layer in the package.

7. The method of claim 1 wherein processing the substrate comprises:
forming a throughhole in the substrate;
depositing a build-up layer on the substrate;
forming traces and vias connected to the throughhole in the build-up layer by imprinting;
plating traces and vias with copper; and
planarizing to remove copper overplate.

8. The method of claim 1 wherein processing the substrate comprises:
depositing a build-up layer on a substrate core, the substrate core having a throughhole;
forming traces and vias connected to the throughhole in the build-up layer by imprinting;
plating traces and vias with copper; and
planarizing to remove copper overplate.

9. A substrate assembly comprises:
a substrate core having a throughhole; and
a first build-up layer deposited on surface of the substrate core, the first build-up layer having traces and vias connected to the throughhole and an interconnecting layer to a semiconductor die via a plurality of bumps;
wherein at least one of the substrate core and the build-up layer is formed by a mixture of a kaolin filler and an epoxy resin.

10. The substrate assembly of claim 9 wherein the first build-up layer is deposited on top surface of the substrate core between the semiconductor die and the substrate core.

11. The substrate assembly of claim 10 further comprising:
a second build-up layer deposited on bottom surface of the substrate core, the second build-up layer having traces and vias connected to the throughhole and the plurality of bumps.

12. The substrate assembly of claim 11 wherein the second build-up layer comprises a mixture of kaolin filler and epoxy resin.

13. The substrate assembly of claim 9 wherein the first build-up layer is deposited on bottom surface of the substrate core between the substrate core and the plurality of bumps.

14. The substrate assembly of claim 13 further comprising:
a second build-up layer deposited on top surface of the substrate core, the second build-up layer having traces and vias connected to the throughhole and the semiconductor die.

15. The substrate assembly of claim 14 wherein the second build-up layer comprises a mixture of kaolin filler and epoxy resin.

16. The substrate assembly of claim 9 wherein the mixture comprises a weight percentage of the kaolin filler between 10% to 70%.

17. The substrate assembly of claim 9 wherein the mixture further comprises a coupling agent.

18. A device comprising:
a semiconductor die; and
a substrate assembly attached to the semiconductor die, the substrate assembly comprising:
a substrate core having a throughhole, and
a first build-up layer deposited on surface of the substrate core, the first build-up layer having traces and vias connected to the throughhole and an interconnecting layer to the semiconductor die via a plurality of bumps;
wherein at least one of the substrate core and the build-up layer is formed by a mixture of a kaolin filler and an epoxy resin.

19. The device of claim 18 wherein the first build-up layer is deposited on top surface of the substrate core between the semiconductor die and the substrate core.

20. The device of claim 19 wherein the substrate assembly further comprises:
a second build-up layer deposited on bottom surface of the substrate core, the second build-up layer having traces and vias connected to the throughhole and the plurality of bumps.

21. The device of claim 20 wherein the second build-up layer comprises a mixture of kaolin filler and epoxy resin.

22. The device of claim 18 wherein the first build-up layer is deposited on bottom surface of the substrate core between the substrate core and the plurality of bumps.

23. The device of claim 22 further comprising:
a second build-up layer deposited on top surface of the substrate core, the second build-up layer having traces and vias connected to the throughhole and the semiconductor die.

24. The device of claim 23 wherein the second build-up layer comprises a mixture of kaolin filler and epoxy resin.

25. The device of claim 18 wherein the mixture comprises a weight percentage of the kaolin filler between 10% to 70%.

26. The device of claim 18 wherein the mixture further comprises a coupling agent.
